(19) United States
(12) Patent Application Publication
(10) Pub. No.: US 2014/0278161 A1
(43) Pub. Date: Sep. 18, 2014

(54) METHOD FOR DETERMINING A SIGNAL TRANSMISSION MODE OF A PLURALITY OF FAULT INDICATORS

(71) Applicant: I-SHOU UNIVERSITY, Kaohsiung (TW)

(72) Inventors: Chao-Shun CHEN, Kaohsiung (TW); Shang-Wen LUAN, Kaohsiung (TW); Jen-Hao TENG, Kaohsiung (TW); Kuo-Chun TING, Kaohsiung (TW); Wei-Hao HUANG, Kaohsiung (TW)

(73) Assignee: I-SHOU UNIVERSITY, Kaohsiung (TW)

(21) Appl. No.: 13/842,637

(22) Filed: Mar. 15, 2013

(51) Int. Cl. G01R 31/08

(52) U.S. Cl. CPC G01R 31/088
USPC 702/59; 702/58

(57) ABSTRACT

A method for determining a signal transmission mode of a plurality of fault indicators includes a data retrieval step, a mode setting step, a number setting step, an analysis step, a first determination step, a calculation step, a second determination step and a mode number increasing step. Based on the above step, the method is able to determine a preferred number of times the fault signals are required to be transmitted between the plurality of fault indicators when a predetermined transmission success rate is met, reducing the energy consumption and prolonging the service life of the indicators.

### BACKGROUND OF THE INVENTION

1. Field of the Invention

The present invention generally relates to a method for determining a signal transmission mode of a plurality of fault indicators and, more particularly, to a method for determining a preferred signal transmission mode of the plurality of fault indicators in a power network.

2. Description of the Related Art

A power company generally transmits power to the user ends via a power network. To monitor the operation of the power network and to quickly determine the fault locations of the power network where malfunctions take place, the power company generally installs a plurality of fault indicators at detection points of the power network to monitor the power transmission.

With reference to FIG. 1, the power network 7 includes at least one power line 71 each having an upstream end 72 and a downstream end 73 according to the transmission direction of the power. Each power line 71 has a plurality of fault indicators 8. When a malfunction takes place in a fault point 9 of a power line 71, a fault current is generated and flows between upstream end 72 and fault point 9. At this time, each of the fault indicators 81, 82 and 83 generates a fault signal. Then, each of fault indicators 81, 82 and 83 sends its fault signal and the received fault signal(s) to a processing center (not shown) of upstream end 72. For example, fault indicator 81 is able to sends its fault signal, as well as the fault signal received from fault indicator 82, to upstream end 72. In this mechanism, the processing center is able to determine the path of the fault current, accurately determining the location of fault point 9.

In general, the plurality of fault indicators 8 transmits signals via a wireless communication system. Therefore, the quantity and communication quality of fault indicators 8 must be taken into consideration when installing fault indicators 8. Two adjacent fault indicators 8 are usually spaced from each other at a predetermined distance in order to prevent the increase in costs resulting from the installation of an excessive amount of fault indicators 8. However, the communication quality between the two adjacent fault indicators 8 is not adequate due to the predetermined distance therebetween. This may result in a failure in transmission of the fault signals. As a result, upstream end 72 is not able to accurately determine the location of fault point 9.

In light of this, the number of transmission times of the fault signals is increased to improve the accuracy in determining the location of fault point 9, as proposed in a conventional method. This ensures each fault indicator 8 to receive the fault signal(s) sent from the adjacent fault indicator 8, improving the accuracy in determining the location of fault point 9. However, the plurality of fault indicators 8 requires larger power consumption due to the increased number of transmission times of the fault signals, resulting in a waste of energy. It even requires an additional cost in replacing the power storage devices of the plurality of fault indicators 8. Thus, it is necessary to provide a method for determining a signal transmission mode of the plurality of fault indicators 8 wherein the method is able to determine a minimal number of times the fault signals are required to be transmitted between the fault indicators 8 when a predetermined transmission success rate is met.

### SUMMARY OF THE INVENTION

It is therefore the objective of this invention to provide a method for determining a signal transmission mode of a plurality of fault indicators wherein the method is able to determine a minimal number of times the fault signals are required to be transmitted between the fault indicators when a predetermined transmission success rate is met.

It is therefore the objective of this invention to provide a method for determining a signal transmission mode of a plurality of fault indicators. The method is able to determine a minimal number of times the fault signals are required to be transmitted between the fault indicators, reducing the energy consumption and maintenance cost of the indicators.

In a preferred embodiment of the invention, a method for determining a signal transmission mode of a plurality of fault indicators comprises a data retrieval step, a mode setting step, a number setting step, an analysis step, a first determination step, a calculation step, a second determination step and a mode number increasing step. The data retrieval step retrieves a location data, a set of communication quality data and a set of fault rate data from a database, as performed by a processor. The mode setting step sets a plurality of signal transmission modes by the processor. The number setting step sets a predetermined number by the processor. The analysis step comprises inputting the location data, the set of communication quality data and the set of fault rate data into a random analysis program, as performed by the processor. The analysis step further comprises generating a fault point in a predetermined one of a plurality of detection zones based on a fault probability of each detection zone specified in the set of fault rate data, as performed by the random analysis program. Two adjacent fault indicators of the plurality of fault indicators form a respective one of the plurality of detection zones therebetween. The generation of the fault point is proportional to the fault probability. The plurality of fault indicators comprises first, second and third fault indicators that are installed between the fault point and an upstream end. The first fault indicator is most adjacent to the fault point among the first, second and third fault indicators. The third fault indicator is most adjacent to the upstream end among the first, second and third fault indicators. The second fault indicator is located between the first and third fault indicators. The analysis step further comprises generating first, second and third fault signals respectively on the first, second and third indicators based on the location data. The first fault indicator transmits the first fault signal to the second fault indicator by “n” times specified in a n^{th} mode of the plurality of signal transmission modes wherein “n” is a mode number of the n^{th} mode of the plurality of signal transmission modes. The second fault indicator transmits the first and second fault signals to the third fault indicator by the “n” times. The third fault indicator transmits the first, second and third fault signals to the upstream end by the “n” times, as performed by the random analysis program. The analysis step further comprises determining a first packet success rate between the first and second fault indicators based on a first cumulative probability therebetween, as well as and a second packet success rate between the second and third fault indicators based on a second cumulative probability therebetween, as performed by the random analysis program. The analysis step further comprises multiplying the first and second packet success rates to obtain a temporary transmission success rate of the n^{th} mode, as performed by the random analysis program. The analysis step further comprises comparing the temporary transmission success rates of a first mode to the n^{th} mode of the plurality of signal transmission modes by the random analysis program, so as to find the largest temporary transmission success rate. The largest temporary transmission success rate is defined as a transmission success rate of the n^{th} mode. The first determination step determines whether a number of times the analysis step has been performed is equal to or larger than the predetermined number. The analysis step is re-performed if the determined result is negative, as performed by the processor. The calculation step determines an average transmission success rate of the transmission success rates under the n^{th} mode, as performed by the processor. The second determination step determines whether the average transmission success rate is larger than a threshold rate, as performed by the processor. The mode number “n” of the n^{th} mode is outputted if the determined result is positive. The mode number increasing step increases the mode number of the n^{th} mode to perform the number setting step.

In a preferred form in shown, the random analysis program is Monte Carlo method.

In the preferred form shown, the location data specifies installation locations of the plurality of indicators in a power network. The set of communication quality data is comprised of a plurality of communication quality data each specifying a communication quality between two adjacent fault indicators of the plurality of fault indicators in the power network. The set of fault rate data is comprised of a plurality of fault rate data each specifying a fault probability of the respective one of the plurality of detection zones.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 shows a diagram of transmission of a plurality of fault signals of a plurality of fault indicators in a power network.

FIG. 2a shows an apparatus adapted to execute a method for determining a signal transmission mode of a plurality of fault indicators according to a preferred embodiment of the invention.

FIG. 2b shows a power network in which the method for determining a signal transmission mode of a plurality of fault indicators of the preferred embodiment of the invention is executed.

FIG. 3 shows a flowchart of the method for determining a signal transmission mode of a plurality of fault indicators according to the preferred embodiment of the invention.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

The terms “upstream end” and “downstream end” are determined according to the transmission direction of the power along a power line. Specifically, when the power flows from a first end to a second end of a power line, the first end is the upstream end, and the second end is the downstream end.

FIG. 2a shows an apparatus adapted to execute a method for determining a signal transmission mode of a plurality of fault indicators in a power network according to a preferred embodiment of the invention is executed. The apparatus is applied to a power network 3 and includes a database 1 and a processor 2. Power network 3 includes at least one power line 31 each having an upstream end 32 and a downstream end 31 A plurality of fault indicators 34 is installed between upstream end 32 and downstream end 33. A detection zone 311 is formed between each two adjacent fault indicators 34. The plurality of fault indicators 34 consists of a first indicator 34a, a second indicator 34b and a third indicator 34c as shown in FIG. 2b.

Database 1 is provided to store a location data, a set of communication quality data and a set of fault rate data. The location data specifies the installation locations of the plurality of indicators 34 in power network 3. The set of communication quality data is comprised of a plurality of communication quality data. Each communication quality data specifies a cumulative probability between each adjacent fault indicator 34 in power network 3, which may be a cumulative distribution function (CDF). The set of fault rate data is comprised of a plurality of fault rate data each specifying a fault probability of a respective detection zone 311. The location data, the set of communication quality data and the set of fault rate data may be obtained from the historical data previously established or collected by the power company.

Processor 2 is electrically connected to database 1 to retrieve data therefrom. Processor 2 may be a computer or any device capable of executing a program for calculation purposes.

FIG. 3 shows a flowchart of the method for determining a signal transmission mode of a plurality of fault indicators according to the preferred embodiment of the invention. The method comprises a data retrieval step S1, a mode setting step S2, a number setting step S3, an analysis step S4, a first determination step S5, a calculation step S6, a second determination step S7 and a mode number increasing step S8.

In data retrieval step S1, processor 2 retrieves the location data, the set of communication quality data and the set of fault rate data from database 1. In mode setting step S2, processor 2 sets a plurality of signal transmission modes. The total number of modes of the plurality of signal transmission modes can be determined by processor 2. An n^{th} signal transmission mode defines that the fault signal(s) is transmitted from an individual indicator 34 to the adjacent indicator 34 (or from the third indicator 34c to upstream end 32) by “n” times along the path to upstream end 32. Specifically, the first signal transmission mode (n=1) defines that each indicator 34 transmits the fault signal(s) to the adjacent indicator 34 by one time, the second signal transmission mode 2 (n=2) defines that each indicator 34 transmits the fault signal(s) to the adjacent indicator 34 by two times. As an example of FIG. 2, when in the first signal transmission mode (N=1), first indicator 34a transmits one fault signal to second indicator 34b by one time, second indicator 34b transmits two fault signals to third indicator 34c by one time, and third indicator 34c transmits three fault signals to upstream end 32 by one time. Similarly, when in the second signal transmission mode (N=2), first indicator 34a transmits one fault signal to second indicator 34b by two times, second indicator 34b transmits two fault signals to third indicator 34c by two times, and third indicator 34c transmits three fault signals to upstream end 32 by two times. Similarly when in the n^{th} signal transmission mode, first indicator 34a transmits one fault signal to second indicator 34b by “n” times, second indicator 34b transmits two fault signals to third indicator 34c by “n” times, and third indicator 34c transmits three fault signals to upstream end 32 by “n” times. The larger the number of “n” the larger number of times the fault signal(s) is transmitted.

The larger the number of “n” the larger a packet success rate between each two adjacent fault indicators 34 (the packet success rate is the probability of successful packet transmission). In other words, the larger number of times the fault signal(s) is transmitted between two adjacent indicators 34 the larger the packet success rate between the two adjacent indicators 34. Advantageously, power network 3 has an improved transmission success rate. To accurately determine a smallest mode from the plurality of signal transmission modes where the corresponding transmission success rate of power network 3 satisfies a threshold value, it is necessary to set the total number of modes of the signal transmission modes as a predetermined value.

Based on this, the transmission success rates of power network 3 under individual signal transmission modes can be calculated in the following step. In this manner, the smallest signal transmission mode where the transmission success rate satisfies the threshold value can be accurately determined. As stated above, the predetermined value may be any positive integer. In this embodiment, the predetermined value is set as 5.

In number setting step S3, processor 2 sets a predetermined number M. The predetermined number M is provided to define the number of times the random analysis is required to be performed by a random analysis program of processor 2. The larger the predetermined number M the more accurate the overall calculation results of the proposed method. The predetermined number M is preferably larger than 50,000. In this embodiment, the predetermined number M is 100,000.

In analysis step S4, processor 2 inputs the location data, the set of communication quality data and the set of fault rate data into the random analysis program, and the random analysis program generates a fault point in a detection zone 311 based on the set of fault rate data. The larger the fault probability of a detection zone 311 the more likely the fault point is generated in the detection zone 311.

Specifically, processor 2 is required to retrieve the set of fault ate data before the fault point is generated in a specific detection zone 311, so that the fault probabilities of all detection zones 311 can be taken into consideration when the random analysis program performs the random analyses. In this manner, the analyzed results would be more accurate. The random analysis program is the Monte Carlo method in this embodiment.

In analysis step S4, the random analysis program controls each fault indicator 34 between the fault point and upstream end 32 to generate a fault signal based on the location data. At this time, each fault indicator 34 transmits one or more fault signals to the adjacent fault indicator 34 by different times along the path to upstream end 32 as specified in the signal transmission modes. Note the fault signals transmitted by an indicator 34 include one fault signal generated by the indicator 34 as well as one or more fault signals received from the other indicator 34.

Specifically, processor 2 retrieves the location data in advance so that the random analysis program is able to accurately determine the locations of the plurality of fault indicators 34. Accordingly, the fault signal(s) is sent from each indicator 34 to the adjacent indicator 34 along the path to upstream end 32 based on the retrieved location data, achieving accurate transmissions of the fault signals.

In this phase, each indicator 34 sends the fault signal(s) to the adjacent indicator 34 upstream by different times as specified in different signal transmission modes. Specifically, when analysis step S4 is performed for the one time, each indicator 34 transmits the fault signal(s) to the adjacent indicator 34 by 1, 2, 3, 4 and 5 times respectively (in the case where the predetermined value is 5 above), as specified in the 5 signal transmission modes.

in analysis step S4, based on the cumulative probability between each two adjacent fault indicators 34 specified in the set of communication quality data, the random analysis program determines the packet success rate between each two adjacent fault indicators 34 under each signal transmission mode. Specifically, the random analysis program determines the packet success rate between each two adjacent fault indicators 34 for the first signal transmission mode (where the fault signals are transmitted by one time), determines another packet success rate between each two adjacent fault indicators 34 for the second signal transmission mode (where the fault signals are transmitted by two times), determines a further packet success rate between each two adjacent fault indicators 34 for the third signal transmission mode (where the fault signals are transmitted by three times) and so on. Based on this, all of the packet success rates of power network 3 under the same signal transmission mode are multiplied to obtain a temporary transmission success rate. As such, 5 temporary transmission success rates of power network 3 can be obtained for the 5 signal transmission modes (in the case where the predetermined value is 5 above). In a case where a temporary transmission success rate is obtained for the n^{th} mode, all of the temporary transmission success rates of the first mode to the n^{th} mode are compared, so as to find the largest temporary transmission success rate among those different signal transmission modes. Finally, the largest temporary transmission success rate is taken as the transmission success rate of the n^{th} signal transmission mode.

In other words, processor 2 retrieves the set of communication quality data in advance so that the communication quality between each two adjacent fault indicators 34 can be taken into consideration when the random analysis program performs the random analysis to determine the packet success rate between each two adjacent fault indicators 34. Thus, the packet success rates of power network 3 can be multiplied to obtain the temporary transmission success rate. Finally, the largest temporary transmission success rate among those temporary transmission success rates of the first mode to the n^{th} mode is determined and defined as the transmission success rate of the n^{th} mode.

For example, assume the temporary transmission success rates (TTSR) of the first to fifth modes are 92.5%, 93.8%, 91.7%, 94.4% and 94.1% respectively, the transmission success rate (TSR) for each signal transmission mode should be the largest temporary transmission success rate, as exemplified below:
TSRₙ₌₁=max [TTSRₙ₌₁=92.5%]=92.5%;
TSRₙ₌₂=max [TTSRₙ₌₁92.5%, TTSRₙ₌₂=93.8%]=93.8%;
TSRₙ₌₃=max [TTSRₙ₌₁=92.5%, TTSRₙ₌₂=93.8%,
TTSRₙ₌₃=91.7%]=93.8%;
TSRₙ₌₄=max [TTSRₙ₌₁=92.5%, TTSR_{n=2=93.8}%, TTSRₙ₌₃=91.7%,
TTSRₙ₌₄=94.4%]=94.4%;
TSRₙ₌₅=max [TTSRₙ₌₁=92.5%, TTSRₙ₌₂=93.8%, TTSRₙ₌₃=91.7%,
TTSRₙ₌₄=94.4%, TTSRₙ₌₅=94.1%]=94.4%.

Therefore, the transmission success rate of n=1 is 92.5% (for the first mode), the transmission success rate of n=2 is 93.8% (for the second mode), the transmission success rate of n=3 is 93.8% (for the third mode), the transmission success rate of n=4 is 94.4% (for the fourth mode), and the transmission success rate of n=5 is 94.4% (for the fifth mode).

When analysis step S4 is finished, the random analysis has been performed by one time.

In first determination step S5, processor 2 determines whether the number of times the random analysis has been performed by analysis step S4 is equal to or larger than the predetermined number M. If the determined result is positive, calculation step S6 is performed, otherwise analysis step S4 is performed.

As stated above, the larger number of times the random analysis is performed the more accurate the overall calculation results can be obtained. Thus, processor 2 is required to determine whether the total number of times that the random analysis is performed by analysis step S4 is equal to or larger than the predetermined number M. If the determined result is negative, analysis step S4 is performed again to determine another 5 transmission success rates of the 5 signal transmission modes under another round of the random analysis, and the determined transmission success rates are saved. If the determined result is positive, calculation step S6 is performed.

In calculation step S6, processor 2 determines an average transmission success rate of the transmission success rates under the current signal transmission mode. Specifically, one transmission success rate of power network 3 under the current signal transmission mode is generated each time analysis step S4 is performed. When the random analysis has been performed by the M times, M transmission success rates of power network 3 may be obtained from the M times operations of the random analysis under the current signal transmission mode. The M transmission success rates of power network 3 in the current signal transmission mode may be averaged out to obtain an average transmission success rate of the current signal transmission mode. For example, when the random analysis has been performed by the M times, M transmission success rates of power network 3 will be obtained for the first signal transmission mode. In this regard, the M transmission success rates can be averaged out to obtain an average transmission success rate of the first signal transmission mode. This is applied to other modes.

In second determination step S7, processor 2 determines whether the average transmission success rate of the current signal transmission mode is larger than a threshold rate. If the determined result is positive, the mode number “n” of the current signal transmission mode is output. If the determined result is negative, mode number increasing step S8 is performed.

Specifically; when the average transmission success rate is larger than the threshold rate, the transmission success rate of power network 3 has reached the required level. At this time, processor 2 is able to output the mode number “n” of the current signal transmission mode to a display for display purposes. The outputted mode number “n” represents the number of times the fault signals are transmitted between two adjacent indicators 34. At this time, the method is finished. To the contrary, if the average transmission success rate is not larger than the threshold rate, it is required to perform mode number increasing step S8 to increase the mode number of the current signal transmission mode (i.e. increase the number of times of the transmission of the fault signal). The threshold rate can be determined by a user and can be 80% or 90% without any limitation.

In mode number increasing step S8, processor 2 retrieves the current signal transmission mode and increases the mode number of the retrieved mode by 1. The procedure then goes back to number setting step S3.

Specifically, processor 2 records the current signal transmission mode. When mode number increasing step S8 is executed, processor 2 increases the recorded mode number by 1 in order for analysis step S4 to be performed again in the increased mode. In this embodiment, number setting step S3 is performed after mode number increasing step S8. At this time, the predetermined number M can be changed, allowing flexible adjustment of the number of times of the random analysis in the following analysis step S4.

Specifically, when the average transmission success rate is not larger than the threshold rate, it indicates the transmission success rate of power network 3 has not yet reached the required level. At this point, mode number increasing step S8 is performed to increase the current mode by one mode in order to increase the number of times the fault signals are transmitted between two adjacent indicators 34. Therefore, analysis step S4 can be performed according to the increased mode. Based on this, the average transmission success rate under the increased mode can be obtained, and it can be determined whether the obtained average transmission success rate is larger than the threshold rate. This is repeatedly performed until the determined average transmission success rate is larger than the threshold rate. When the average transmission success rate is larger than the threshold rate, the mode number of the average transmission success rate is outputted. The proposed method is finished.

In conclusion, the random analysis in the embodiment is performed based on the Monte Carlo method to determine the average transmission success rate under each signal transmission mode. When the average transmission success rate is not larger than the threshold rate, the mode number is increased by 1 in order for the random analyses to be performed again. Based on this, the smallest signal transmission mode where the average transmission success rate is larger than the threshold rate can be determined. Advantageously, the energy consumption and the maintenance cost of indicators 34 can be reduced.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A method for determining a signal transmission mode of a plurality of fault indicators, comprising:
a data retrieval step retrieving a location data, a set of communication quality data and a set of fault rate data from a database, as performed by a processor;
a mode setting step setting a plurality of signal transmission modes by the processor;
a number setting step setting a predetermined number by the processor;
an analysis step comprising:
inputting the location data, the set of communication quality data and the set of fault rate data into a random analysis program, as performed by the processor;
generating a fault point in a predetermined one of a plurality of detection zones based on a fault probability of each detection zone specified in the set of fault rate data, as performed by the random analysis program, wherein two adjacent fault indicators of the plurality of fault indicators form a respective one of the plurality of detection zones therebetween, wherein the generation of the fault point is proportional to the fault probability, wherein the plurality of fault indicators comprises first, second and third fault indicators that are installed between the fault point and an upstream end, wherein the first fault indicator is most adjacent to the fault point among the first, second and third fault indicators, wherein the third fault indicator is most adjacent to the upstream end among the first, second and third fault indicators, and wherein the second fault indicator is located between the first and third fault indicators;
generating first, second and third fault signals respectively on the first, second and third indicators based on the location data, wherein the first fault indicator transmits the first fault signal to the second fault indicator by “n” times specified in a n^{th} mode of the plurality of signal transmission modes, wherein “n” is a mode number of the n^{th} mode of the plurality of signal transmission modes, wherein the second fault indicator transmits the first and second fault signals to the third fault indicator by the “n” times, wherein the third fault indicator transmits the first, second and third fault signals to the upstream end by the “n” times, as performed by the random analysis program;
determining a first packet success rate between the first and second fault indicators based on a first cumulative probability therebetween, as well as and a second packet success rate between the second and third fault indicators based on a second cumulative probability therebetween, as performed by the random analysis program;
multiplying the first and second packet success rates to obtain a temporary transmission success rate of the n^{th} mode, as performed by the random analysis program; and
comparing the temporary transmission success rates of a first mode to the n^{th} mode of the plurality of signal transmission modes by the random analysis program, so as to find the largest temporary transmission success rate among the first mode to the n^{th} mode, wherein the largest temporary transmission success rate is defined as a transmission success rate of the n^{th} mode;
a first determination step determining whether a number of times the analysis step has been performed is equal to or larger than the predetermined number, as performed by the processor, wherein the analysis step is re-performed if the determined result is negative;
a calculation step determining an average transmission success rate of the transmission success rates under the n^{th} mode, as performed by the processor;
a second determination step determining whether the average transmission success rate is larger than a threshold rate, as performed by the processor, wherein the mode number “n” of the n^{th} mode is outputted if the determined result is positive; and
a mode number increasing step increasing the mode number of the n^{th} mode to perform the number setting step.

2. The method for determining a signal transmission mode of a plurality of fault indicators as claimed in claim 1, wherein the random analysis program is Monte Carlo method.

3. The method for determining a signal transmission mode of a plurality of fault indicators as claimed in claim 1, wherein the location data specifies installation locations of the plurality of indicators in a power network, wherein the set of communication quality data is comprised of a plurality of communication quality data each specifying a communication quality between two adjacent fault indicators of the plurality of fault indicators in the power network, and wherein the set of fault rate data is comprised of a plurality of fault rate data each specifying a fault probability of the respective one of the plurality of detection zones.
